(19) United States
(12) Patent Application Publication
(10) Pub. No.: US 2009/0298291 A1
(43) Pub. Date: Dec. 3, 2009

(54) METHOD FOR FORMING A PATTERN OF A SEMICONDUCTOR DEVICE

(75) Inventors: Sung Koo LEE, Seoul (KR); Jae Chang Jung, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/259,962

(22) Filed: Oct. 28, 2008

(30) Foreign Application Priority Data
May 29, 2008 (KR) 10-2008-0050506

(51) Int. Cl. H01L 21/3213

(52) U.S. Cl. 438/694; 257/E21.308

(57) ABSTRACT

In a method for forming a pattern of a semiconductor device, an ultra fine pattern is formed using a spacer patterning technology to overcome resolution limits of an exposer. A silicon-containing resist enhancement lithography assisted by a chemical shrink (RELACS) layer is formed with a spin-con-coating method in a track apparatus over a photoresist pattern. As a result, a cross-linking reaction is generated between the RELACS layer and the photoresist patterns to form the spacer, and the spacer is used as a mask in the patterning process.

### CROSS-REFERENCES TO RELATED APPLICATIONS

Priority is claimed to Korean patent application number 10-2008-0050506, filed on May 29, 2008, which is incorporated by reference in its entirety.

### BACKGROUND OF THE INVENTION

The present invention generally relates to a method for forming a pattern of a semiconductor device, and, more specifically, to a method for forming an ultra fine pattern using a spacer patterning technology to overcome resolution limits of an exposer in the manufacture of semiconductor devices.

In order to improve integration of the device, a photolithography technology has been used. The photolithography technology is performed to form fine patterns with light sources using chemically amplified Deep Ultra Violet (DUV) light sources such as ArF (193 nm) and VUV (157 nm) and photoresist materials suitable for the exposure light sources.

As a semiconductor device becomes smaller, it is important to control a critical dimension of a pattern line-width in the photolithography technology. Generally, the processing speed of semiconductor devices depends on the critical dimension of the pattern line-width. For example, when the size of the pattern line-width is decreased, the processing speed is increased to improve device performance.

However, it is difficult to form a line and space (L/S) pattern of less than 40 nm by a single exposure process in the photolithography process using an ArF exposer having a common numerical aperture of less than 1.2.

In order to improve resolution of photolithography 1o technology and extend a process margin, a double patterning technology has been developed. The double patterning technology includes processes whereby a photoresist-coated wafer is exposed by two masks, and then developed.

Since the double patterning technology uses two masks for patterning, the process is complicated when a single mask is used, and the manufacturing cost and the turn-around-time are lower than those of a single patterning technology using a single mask, thereby degrading the throughput. When a pattern having a smaller pitch than a resolution limit of the exposer is formed in the cell region, illusory images are overlapped. As a result, the double patterning technology does not obtain a desired pattern. Furthermore, during alignment, overlays may be mis-aligned.

In order to prevent overlapping and mis-alignment, a double patterning technology (DPT) and a spacer patterning technology (SPT) have been developed.

The DPT comprises forming a first pattern having a line-width twice as large as that of a desired pattern, and forming a second pattern having the same line-width between the first patterns. More specifically, the DPT includes a positive method and a negative method.

As shown in FIG. 1, in the positive method, a stack structure including an underlying layer 12, a first mask film 14, a second mask film 16 and first positive photoresist patterns 18a is formed over a semiconductor substrate 10. The second mask film 16 is etched using the first photoresist patterns 18a as an etching mask to form second mask patterns 16a. The second positive photoresist patterns 18b are formed between the second mask patterns 16a. The first mask film 14 is etched using the second mask patterns 16a and the second positive photoresist patterns 18b as an etching mask to obtain the first mask patterns 14a.

As shown in FIG. 2, in the negative method, a stack structure including an underlying layer 22, a first mask film 24, a second mask film 26 and first negative photoresist patterns 28a is formed over a semiconductor substrate 20. A second mask film 26 is etched using the first negative photoresist patterns 28a as an etching mask to form second mask patterns 26a. The second negative photoresist patterns 28b are formed over the second mask patterns 26a. The second mask patterns 26a are re-etched using the second negative photoresist patterns 28b as an etching mask to form the second mask patterns 26b. The second negative photoresist patterns 28b are removed, and the first mask film 24 is etched using the second mask patterns 26b as an etching mask to obtain the first mask patterns 24a.

Since the DPT uses two kinds of masks, it is possible to form a pattern having a desired resolution. However, the process steps are complicated, and the manufacturing cost is increased. Moreover, when the second photoresist pattern is formed, mis-alignment occurs.

The SPT is a self-alignment technology to prevent mis-alignment by performing a mask process for forming a pattern in a cell region. The SPT includes a positive method and a negative method.

As shown in FIG. 3, in the positive method, a stack structure including an underlying layer 32, a first mask film 34, a second mask film 36 and photoresist patterns 38a is formed over a semiconductor substrate 30. A second mask film 36 is etched using the photoresist pattern 38a as an etching mask to form second mask patterns 36a. A spacer 38b is formed on sidewalls of the second mask patterns 36a. The second mask patterns 36a are removed, and a first mask film 34 is etched using the spacer 38b as an etching mask to obtain first mask patterns 34a.

As shown in FIG. 4, the negative method includes forming a stack structure including an underlying layer 42, a first mask film 44, a second mask film 46 and a photoresist pattern 48a over a semiconductor substrate 40. A second mask film 46 is etched using the photoresist pattern 48a as an etching mask to form second mask patterns 46a. A spacer 48b is formed on sidewalls of the second mask pattern 46a. A spin-on-glass-film 50 is coated over the resulting structure. A CMP or an etch-back method is performed to expose the second mask patterns 46a and the spacer 48b. The spacer 48b is removed, and a first mask film 44 is etched using the second mask pattern 46a and the spin-on-carbon-film 50 as an etching mask to obtain the first mask patterns 44a.

FIG. 5 is a cross-sectional diagram illustrating a conventional SPT method. The underlying layer 32, a plurality of the first mask films 34 and the second mask patterns 36a consisting of an amorphous carbon are formed over the semiconductor substrate 30.

A nitride film 38 is formed with chemical vapor deposition (CVD) method on the first mask film 34 including the second mask patterns 36a. An etch-back process is performed to etch the nitride film 38, thereby forming the spacer 38b on sidewalls of the second mask patterns 36a.

After the second mask pattern 36a is removed, a polysilicon film included in the top layer of the plurality of the first mask films 34 is etched using the residual spacer 38b as an etching mask, thereby obtaining the first mask pattern 34a. The spacer 38b used as an etching mask is removed.

As mentioned above, since a nitride film is used by a CVD method and a multi-layered mask film is applied in order to 10 form a spacer in the conventional SPT method, the etching process is repeated. As a result, the process is complicated, the manufacturing cost is high, and the process time is long. Moreover, the investment and manufacturing process of CVD equipment are complicated and do not facilitate the production of devices. Particularly, since the spacer is transformed to have a horn shape after the etch-back process as the critical dimension of the spacer becomes smaller, the pattern profile is degraded.

### BRIEF SUMMARY OF THE INVENTION

Various embodiments of the present invention are directed at providing a method for forming a pattern of a semiconductor device. In the method, a film such as nitride film is not formed by an additional CVD method in order to form a spacer through a SPT method. A silicon-containing resist enhancement lithography assisted by chemical shrink (RELACS) layer is formed with a spin-con-coating method in a track equipment over a photoresist pattern. As a result, a cross-linking reaction is generated between the RELACS layer and the photoresist patterns to form a spacer, and the spacer is used as a mask in a patterning process.

According to an embodiment of the present invention, a method for forming a pattern of a semiconductor device comprises forming a stack film including an underlying layer and an antireflection film over a semiconductor substrate. A photoresist pattern comprises a self-assembly barrier film in a top portion of the photoresist pattern.

A silicon-containing RELACS material is formed over the stack film including the photoresist pattern. The silicon-containing RELACS material includes a polyvinylpyrrolidone derivative as a base resin. The silicon-containing RELACS material includes the silicon element, and the silicon element is present in an amount ranging from 15 wt % to 45 wt % by weight based on the total material molecular weight. The silicon-containing RELACS material is baked at a temperature of 100° C. to 190° C. to form a silicon-containing RELACS layer. The thickness of the silicon-containing RELACS layer ranges from 800 Å to 1500 Å. As a result, a cross-linking layer that is used as a spacer is formed between the silicon-containing RELACS layer and sidewalls of the photoresist pattern. The silicon-containing RELACS layer is removed to form a spacer on sidewalls of the photoresist pattern. The thickness of the spacer ranges from 15 nm to 20 nm.

The photoresist pattern is removed with an O₂ plasma. The stack film is etched using the spacer as an etching mask to form a stack pattern.

According to another embodiment of the present invention, a method for forming a pattern of a semiconductor device comprises: forming a stack film including an underlying layer and an antireflection film over a semiconductor substrate; forming a lo photoresist pattern; forming a RELACS layer over the stack film including the photoresist pattern; forming a silicon-containing RELACS layer over the RELACS layer; etching the silicon-containing RELACS layer and the RELACS layer to form a spacer on sidewalls of the photoresist pattern; removing the photoresist pattern; and etching the stack film using the spacer as a mask to form a stack pattern.

The forming-a-RELACS-layer step comprises forming the RELACS-material; and baking the RELACS-material at temperature of 110° C. to 150° C. The thickness of the RELACS layer ranges from 800 Å to 1500 Å.

The forming-a-silicon-containing-RELACS-layer step comprises forming the silicon-containing-RELACS-material, and baking the silicon-containing-RELACS-material at temperature of 100° C. to 190° C. A thickness of the silicon-containing RELACS layer ranges from 800 Å to 1500 Å. The cross-linking reaction occurs between the photoresist pattern and the RELACS layer during the baking process so that a cross-linking layer used as a spacer is formed on the surface of the photoresist pattern.

The-etching-the-RELACS-layers process further comprises performing an etch-back process on the RELACS layers to remove the RELACS layers positioned in a top portion of the photoresist pattern. The thickness of the spacer ranges from 20 nm to 40 nm after the photoresist pattern is removed.

Also, a semiconductor device comprises a pattern formed by the above-described methods.

### BRIEF DESCRIPTION OF THE DRAWINGS

FIG. 1 is a cross-sectional diagram illustrating a conventional positive double patterning method.

FIG. 2 is a cross-sectional diagram illustrating a conventional negative double patterning method.

FIG. 3 is a cross-sectional diagram illustrating a conventional positive spacer patterning method.

FIG. 4 is a cross-sectional diagram illustrating a conventional negative spacer patterning method.

FIG. 5 is a cross-sectional diagram illustrating a conventional spacer patterning method.

FIGS. 6a to 6g are cross-sectional diagrams illustrating a method for forming a pattern of a semiconductor device according to an embodiment of the present invention.

FIG. 7 is a cross-sectional diagram of a photoresist film formed by spin-coating according to an embodiment of the present invention.

FIG. 8 is a SEM photograph illustrating a pattern before and after reaction of photoresist and silicon-containing RELACS materials according to an embodiment of the present invention.

FIGS. 9a to 9h are cross-sectional diagrams illustrating a method for forming a pattern of a semiconductor device according to another embodiment of the present invention.

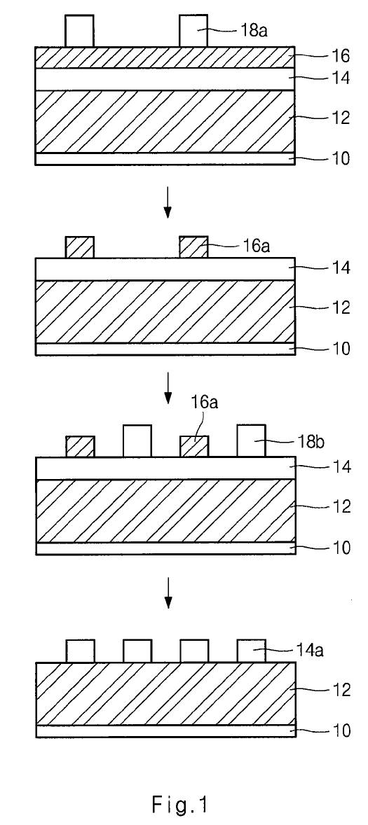

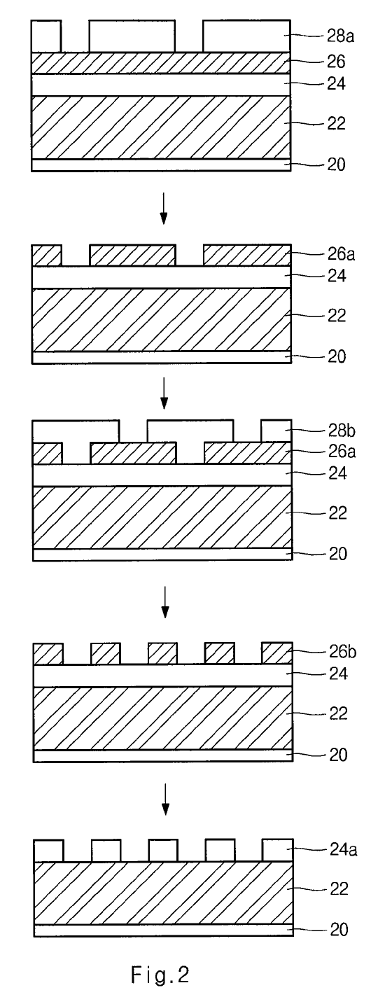

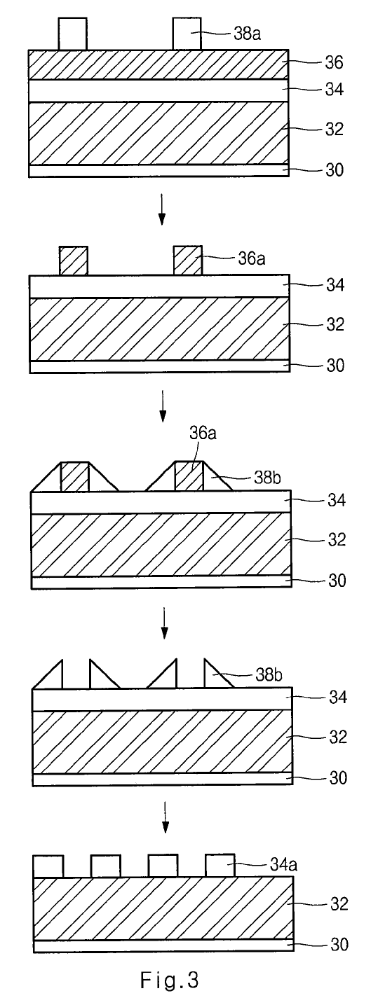

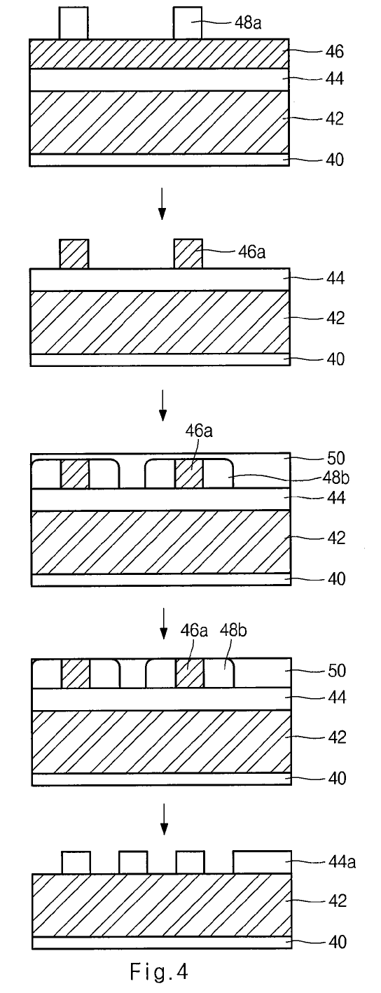

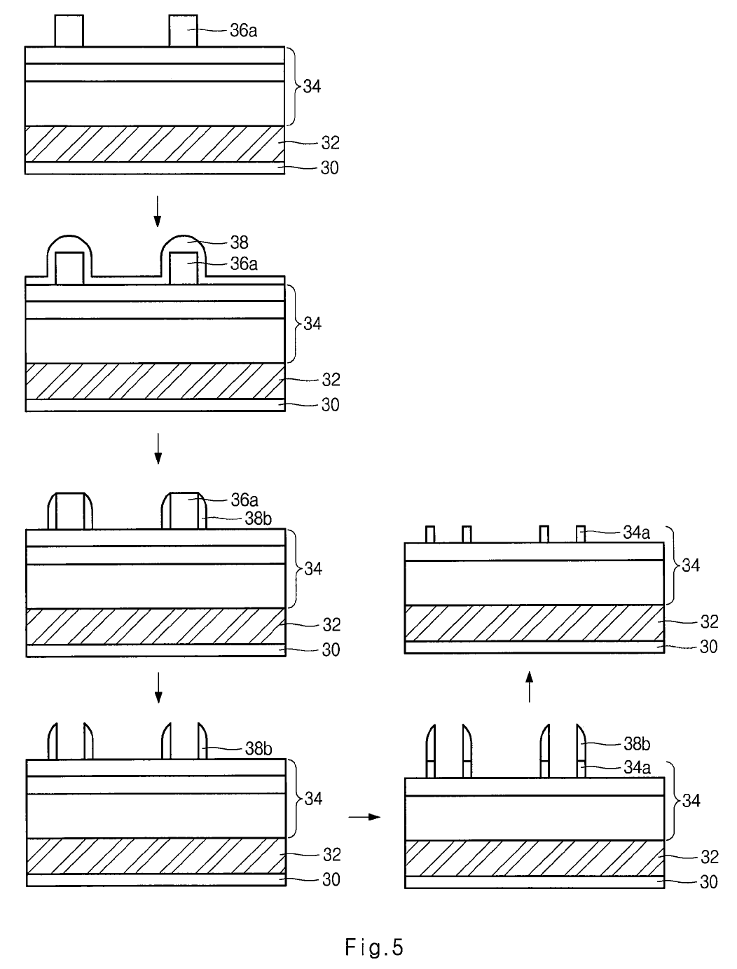

### DESCRIPTION OF EMBODIMENTS

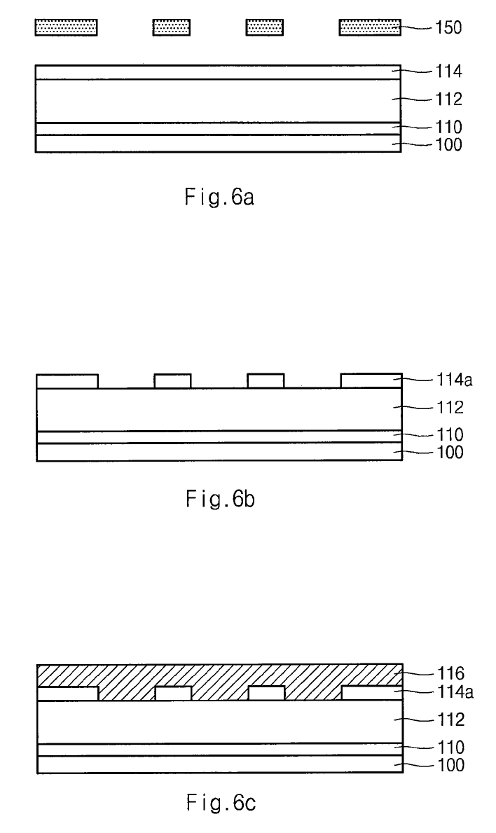

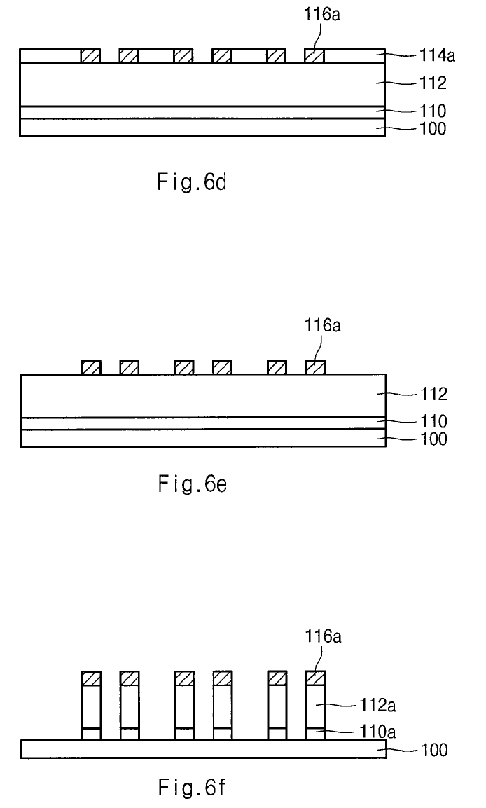

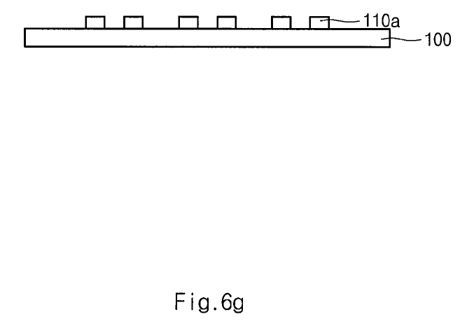

FIGS. 6a to 6g are cross-sectional diagrams illustrating a method for forming a pattern of a semiconductor device according to an embodiment of the present invention.

Referring to FIG. 6a, a stack film including an underlying layer 110 and an antireflection film 112 is formed over a semiconductor substrate 100. A photoresist composition is spin-coated over the antireflection film 112, and baked to form a photoresist film 114 at a thickness ranging from 900 Å to 1100 Å for constituting a self-assembly barrier film.

The self-assembly barrier film, which is called a block layer, is not formed additionally, but is embedded in the photoresist film 114, so that it may be called an embedded barrier layer.

The photoresist film 114 is formed by a photoresist composition including an acrylic polymer as a base resin, and including a photoacid generator and an organic solvent.

In the embodiment, a photoresist for an embedded barrier film having a surface modifying group (produced by Rohm and Hass Co.) is used.

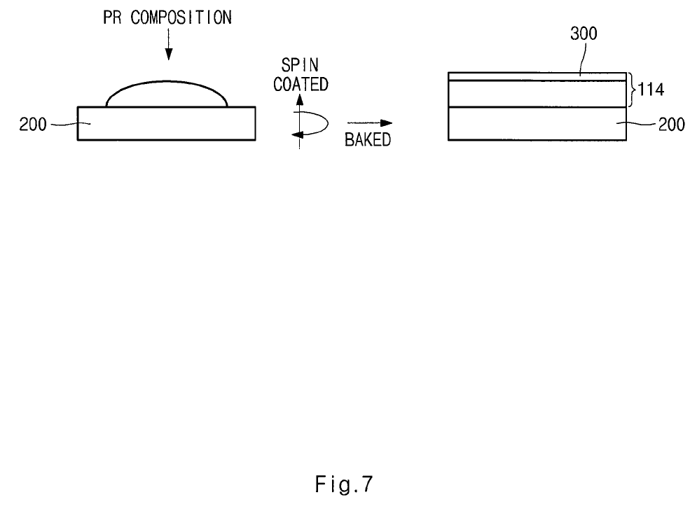

FIG. 7 is a cross-sectional diagram of the photoresist film 114 formed by spin-coating according to an embodiment of the present invention. As shown in FIG. 7, after the photoresist composition is lo spin-coated over the stack film 200 and baked, a self-assembly barrier film 300 is formed over a top portion of the resulting structure.

An exposing process using a cell mask 150 and a developing process are performed on the photoresist film 114 for constituting the self-assembly film. As a result, as shown in FIG. 6b, a photoresist pattern 114a is formed.

The self-assembly barrier film is formed over the photoresist film 114, thereby preventing inhibition of acid generation in a region including the self-assembly barrier film in the exposing process.

Referring to FIG. 6c, a silicon-containing RELACS material is coated over the antireflection film 112 including the photoresist pattern 114a, and baked at a temperature ranging from 100° C. to 190° C., preferably, 110° C. to 170° C., for 90 seconds, thereby obtaining a silicon-containing RELACS layer 116.

The coating process is performed by a spin-on-coating method in a track apparatus.

The RELACS material (produced by AZ Electronic Materials Co.) is used to reduce the size of the contact hole. Specifically, a photoresist pattern is formed on a semiconductor substrate. A RELACS material is coated over the photoresist pattern, and baked to cause a cross-linking reaction between the RELACS material and the photoresist pattern. As a result, a cross-linking layer is formed on the surface of the photoresist pattern, thereby reducing a gap between patterns and the size of the contact hole.

The silicon-containing RELACS material includes a polyvinylprrolidone derivative as a base resin, where a silicon element is present in an amount ranging from 15 wt % to 45 wt % by weight based on the total material molecular weight.

The silicon-containing RELACS layer 116 is formed using AZ LExp. SS-001 (produced by AZ Electronic Materials Co.). As a result, the RELACS layer 116 has an excellent etching resistance and facilitates regulation of the etching selectivity.

When the RELACS layer 116 is formed, the thickness of the cross-linking layer (not shown) formed on the surface of the photoresist pattern 114a can be adjusted by regulating the baking temperature and the type of the RELACS material. As a result, it is possible to regulate a desired critical dimension of the spacer.

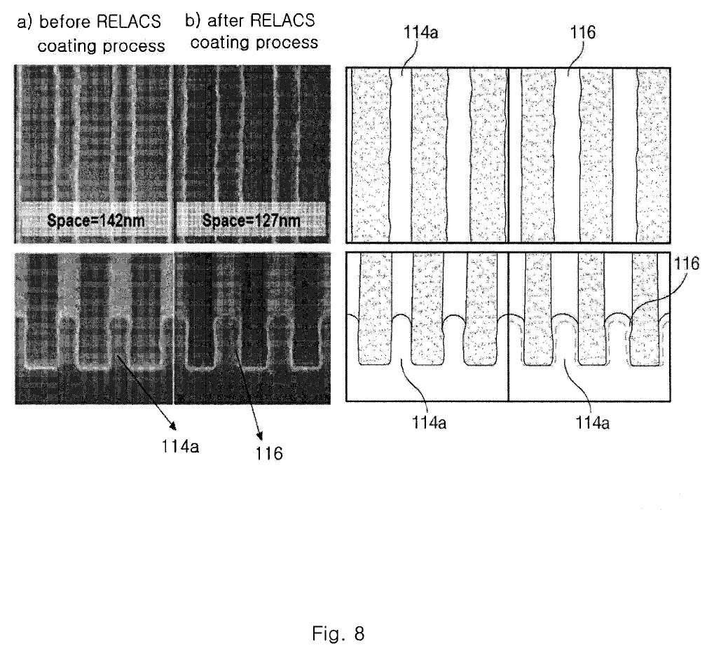

FIG. 8 is a SEM photograph illustrating a pattern before and after a cross-linking reaction of photoresist and silicon-containing RELACS materials according to an embodiment of the present invention. A gap between the photoresist patterns 114a is 142 nm before the RELACS layer 116 is formed over the photoresist pattern 114a. However, the gap between the photoresist patterns 114a is reduced by 15 nm to 127 nm after the RELACS layer 116 is formed over the photoresist pattern 114a and the cross-linking reaction occurs.

A cross-linking reaction occurs between the RELACS layer 116 and sidewalls of the photoresist pattern 114a having no self-assembly barrier film during the baking process. However, the cross-linking reaction does not occur between the RELACS layer 116 and the top portion of the photoresist pattern 114a because acid generation is inhibited in a region having a self-assembly barrier film.

Referring to FIG. 6d, when the RELACS layer 116 is removed with a thinner or a developer, the cross-linking layer positioned on sidewalls of the photoresist pattern 114a is not removed by the removing process, but remains to form a spacer 116a having a thickness ranging from 15 nm to 20 nm.

It is unnecessary to perform an etch-back process for removing the RELACS layer 116 positioned on the top portion of the photoresist pattern 114a when the spacer is formed, thereby simplifying the process.

Referring to FIG. 6e, the photoresist pattern 114a is removed with an O₂ plasma.

Referring to FIG. 6f, the antireflection film 112 and the underlying layer 110 are etched using the spacer 116a as an etching mask, thereby obtaining an antireflection pattern 112a and an underlying pattern 110a.

Referring to FIG. 6g, the spacer 116a and the antireflection pattern 112a are removed to form the underlying pattern 110a.

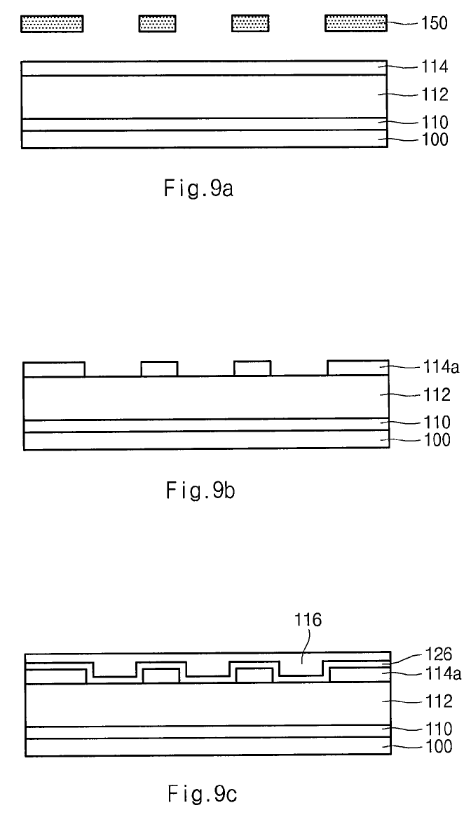

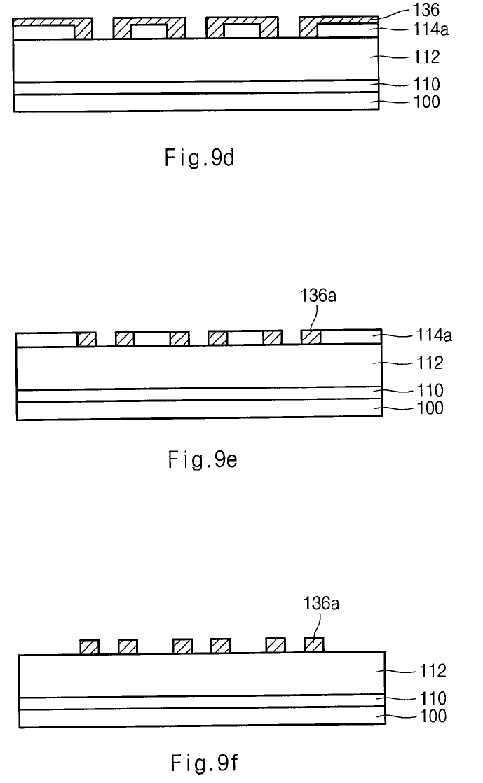

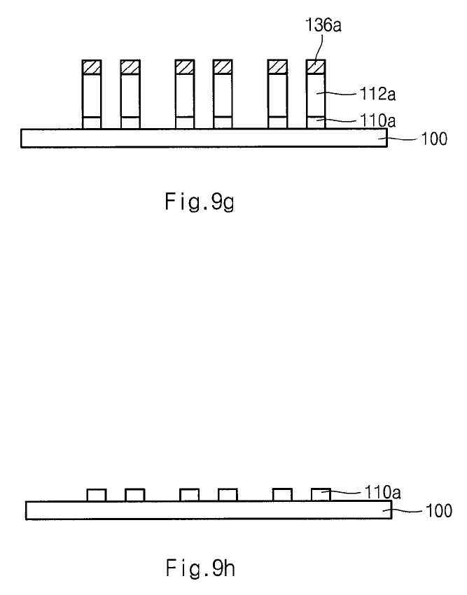

FIGS. 9a to 9h are cross-sectional diagrams illustrating a method for forming a pattern of a semiconductor device according to another embodiment of the present invention. In order to increase the amount of RELACS material attached to the photoresist pattern and to improve the critical dimension uniformity (CDU) of the spacer, a common RELACS material is coated, and a silicon-containing RELACS material is then coated on the resulting structure.

Referring to FIG. 9a, a stack film including the underlying layer 110 and the antireflection film 112 is formed over the semiconductor substrate 100. The photoresist composition is spin-coated over the antireflection film 112, and baked to form the photoresist film 114 for constituting a self-assembly barrier film at a thickness ranging from 900 Å to 1100 Å over the top portion of the resulting structure.

An exposing process with the cell mask 150 and a developing process are performed on the photoresist film 114. As a result, a photoresist pattern 114a is formed as shown in FIG. 9b.

Referring to FIG. 9c, the RELACS material (AZ Exp. R607 produced by AZ Electronic Material Co.) is coated over the antireflection film 112 including the photoresist pattern 114a, and baked at a temperature ranging from 110° C. to 150° C. for 90 seconds, thereby obtaining a RELACS layer 126 having a thickness ranging from 800 Å to 1500 Å.

The RELACS layer 126 is formed so as to increase the amount of the RELACS material attached to the photoresist pattern 114a before the silicon-containing RELACS layer 116 is formed.

The silicon-containing RELACS material (AZ LExp. SS-001 produced by AZ Electronic Materials Co.) is coated over the RELACS layer 126, and baked at a temperature ranging from 100° C. to 190° C., preferably, from 110° C. to 170° C., for 90 seconds, thereby obtaining a silicon-containing RELACS layer 116 having a thickness ranging from 800 Å to 1500 Å. A cross-linking reaction occurs between the RELACS layer 126 and the photoresist pattern 114a during the exposing baking process, thereby forming a cross-linking layer (not shown) on the surface of the photoresist pattern 114a.

Referring to FIG. 9d, the silicon-containing RELACS layer 116 and the RELACS layer 126 are removed with a thinner or a developer.

As a result, only a cross-linking layer 136 remains over the photoresist pattern 114a. In other words, the cross-linking layer 136 positioned in the top portion of the photoresist pattern 114a is not completely removed because the RELACS layer 126 and the silicon-containing RELACS layer 116 are thickly formed over the photoresist pattern 114a.

Referring to FIG. 9e, a wet or dry etch-back process is performed on the cross-linking layer 136 positioned in the top portion of the photoresist pattern 114a so as to remove the cross-linking layer 136 positioned in the top portion of the photoresist pattern 114a, thereby obtaining a spacer 136a having a thickness ranging from 20 nm to 40 nm on sidewalls of the photoresist pattern 114a.

Referring to FIG. 9f, the photoresist pattern 114a is removed with an O₂ plasma.

Referring to FIG. 9g, the antireflection film 112 and the underlying layer 110 are etched using the spacer 116a as a mask to form the antireflection pattern 112a and the underlying pattern 110a.

Referring to FIG. 9h, the spacer 116a and the antireflection pattern 112a are removed to obtain the underlying pattern 110a.

As described above, a simple SPT including a spin-on-coating method by photolithography is performed in the embodiment of the present invention, thereby simplifying the process and reducing the manufacturing cost and time. Also, it is easy to regulate a thickness of the cross-linking layer used as a spacer by a baking temperature, and by changing the type of RELACS material and photoresist.

In the embodiment of the present invention, an etch-back process for removing a spacer formed over a photoresist is not performed during an etching process, thereby preventing degradation of the spacer. Moreover, the SPT including one mask process is performed, thereby preventing mis-arrangement.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for forming a pattern of a semiconductor device, the method comprising:
forming a stack film including an underlying layer and an antireflection film over a semiconductor substrate;
forming a photoresist pattern over the stack film;
forming a silicon-containing resist enhancement lithography assisted by chemical shrink (RELACS) layer over the photoresist pattern and the stack film;
removing the silicon-containing RELACS layer to form a spacer on sidewalls of the photoresist pattern;
removing the photoresist pattern; and
etching the stack film using the spacer as a etching mask to form a stack pattern.

2. The method according to claim 1, wherein the photoresist pattern comprises a self-assembly barrier film in a top portion of the photoresist pattern.

3. The method according to claim 1, wherein the forming-a-silicon-containing-RELACS-layer step comprises:
coating a silicon-containing RELACS material over the photoresist pattern and the stack film; and
baking the silicon-containing RELACS material.

4. The method according to claim 3, wherein the silicon-containing RELACS material includes a polyvinylpyrrolidone derivative as a base resin.

5. The method according to claim 4, wherein the silicon-containing RELACS material includes a silicon element, and the silicon element is present in an amount ranging from 15 wt % to 45 wt % by weight based on the total material molecular weight.

6. The method according to claim 3, wherein the baking process is performed at 100° C. to 190° C.

7. The method according to claim 3, wherein a cross-linking reaction occurs between sidewalls of the photoresist pattern and the silicon-containing RELACS layer during the baking process so that a cross-linking layer used as a spacer is formed on sidewalls of the photoresist pattern.

8. The method according to claim 1, wherein the thickness of the silicon-containing RELACS layer ranges from 800 Å to 1500 Å.

9. The method according to claim 1, wherein the removing-the-photoresist-pattern step is performed with an 02 plasma.

10. The method according to claim 1, wherein a thickness of the spacer ranges from 15 nm to 20 nm after the photoresist pattern is removed.

11. A method for forming a pattern of a semiconductor device, the method comprising:
forming a stack film including an underlying layer and an antireflection film over a semiconductor substrate;
forming a photoresist pattern over the stack film;
forming a resist enhancement lithography assisted by chemical shrink (RELACS) layer over the photoresist pattern and the stack film including;
forming a silicon-containing RELACS layer over the RELACS layer;
etching the silicon-containing RELACS layer and the RELACS layer to form a spacer on sidewalls of the photoresist pattern;
removing the photoresist pattern; and
etching the stack film using the spacer as an etching mask to form a stack pattern.

12. The method according to claim 11, wherein the forming-a-RELACS-layer step comprises:
forming the RELACS-material; and
baking the RELACS-material at temperature of 110° C. to 150° C.

13. The method according to claim 11, wherein a thickness of the RELACS layer ranges from 800 Å to 1500 Å.

14. The method according to claim 11, wherein the forming-a-silicon-containing-RELACS-layer step comprises:
forming the silicon-containing-RELACS-material; and
baking the silicon-containing-RELACS-material at 100° C. to 190° C.

15. The method according to claim 11, wherein the thickness of the silicon-containing RELACS layer ranges from 800 Å to 1500 Å.

16. The method according to one of claims 12 and 14, wherein a cross-linking reaction occurs between the photoresist pattern and the RELACS layer during the baking process so that a cross-linking layer used as a spacer is formed on a surface of the photoresist pattern.

17. The method according to claim 11, wherein the etching-the-RELACS-layers process further comprises performing an etch-back process on the RELACS layers to remove the RELACS layers positioned in a top portion of the photoresist pattern.

18. The method according to claim 11, wherein a thickness of the spacer ranges from 20 nm to 40 nm after the photoresist pattern is removed.
